(19) United States
(12) Patent Application Publication
(10) Pub. No.: US 2012/0177231 A1
(43) Pub. Date: Jul. 12, 2012

(54) INTERACTIVE PLAY SYSTEM

(75) Inventor: Chao-Tung Yang, Hsinchu (TW)

(73) Assignee: LINGO LIMITED, Kowloon (HK)

(21) Appl. No.: 13/346,735

(22) Filed: Jan. 10, 2012

(30) Foreign Application Priority Data
Jan. 10, 2011 (TW) 100200521

(51) Int. Cl. H03F 99/00

(52) U.S. Cl. 381/120

(57) ABSTRACT

An interactive play system including a handheld device and an insertion device is provided. An interactive application program is embedded in the handheld device. The insertion device includes a dock, an amplifier, a speaker, and a slave circuit. The dock carries the handheld device. The speaker is coupled to the amplifier and used for playing a sound. The slave circuit is coupled to the amplifier. When the handheld device is placed in the dock of the insertion device and accordingly activates the interactive application program, the handheld device displays an interactive graphical user interface, and the slave circuit and the amplifier are coupled to the handheld device, so as to guide a user to set the insertion device. The handheld device controls various functions of the slave circuit.

### CROSS-REFERENCE TO RELATED APPLICATION

This application claims the priority benefit of Taiwan application serial no. 100200521, filed Jan. 10, 2011. The entirety of the above-mentioned patent application is hereby incorporated by reference herein and made a part of this specification.

### BACKGROUND OF THE INVENTION

1. Field of the Invention

The invention generally relates to an interactive system, and more particularly, to an interactive play system which adds additional functions to a handheld device.

2. Description of Related Art

Along with the widespread of handheld devices (for example, smart phones, personal digital assistants (PDAs), and portable digital multimedia players), many different kinds of accessories have been developed. One kind of accessory which allows a handheld device to amplify its sound through an exclusive speaker is provided.

FIG. 1 illustrates a conventional insertion speaker. The insertion speaker has a dock for inserting a handheld device. Such insertion speakers are all based on such a simple principle that only the sound signals are amplified by using an amplifier and then played by using a speaker. Herein the insertion speaker and the handheld device cannot transmit signals or messages in two directions.

Another kind of accessory for charging a handheld device and expanding the functionality of an insertion speaker is provided. Such an accessory, similar to that illustrated in FIG. 1, can charge a handheld device besides amplifying the sound by using an exclusive speaker.

An existing insertion speaker and an existing handheld device are two individual units and cannot transmit data, signals, or messages to each other. Since the handheld device cannot control the insertion speaker, a user cannot directly use additional functions of the insertion speaker through the handheld device.

### SUMMARY OF THE INVENTION

Accordingly, the invention is directed to an interactive play system which resolves aforementioned problems in the conventional techniques.

According to an exemplary embodiment of the invention, an interactive play system including a handheld device and an insertion device is provided. An interactive application program is embedded in the handheld device. The insertion device includes a dock, an amplifier, a speaker, and a slave circuit. The dock carries the handheld device. The speaker is coupled to the amplifier and is used for playing a sound. The slave circuit is coupled to the amplifier. When the handheld device is placed into the dock of the insertion device and accordingly activates the interactive application program, the handheld device displays an interactive graphical user interface, and the slave circuit and the amplifier are coupled to the handheld device, so as to guide a user to set the insertion device. The handheld device controls various functions of the slave circuit.

According to an exemplary embodiment of the invention, the slave circuit includes a connector, a radio frequency integrated circuit (RFIC), a demodulator/decompressor, and a digital-to-analog converter (DAC). The connector is coupled to the handheld device so as to allow the handheld device and the insertion device to communicate with each other. The RFIC receives a radio frequency signal and converts the radio frequency signal to an intermediate frequency (IF) signal. The demodulator/decompressor is coupled between the RFIC and the connector. The demodulator/decompressor receives the IF signal from the RFIC and demodulates and decompresses the IF signal under the control of a central processing unit (CPU) of the handheld device. The DAC is coupled between the demodulator/decompressor and the amplifier, wherein a decompressed digital signal is processed by the DAC and the amplifier and then played through the speaker.

According to an exemplary embodiment of the invention, the insertion device records a multimedia file in real time when the insertion device demodulates and decompresses the IF signal.

According to an exemplary embodiment of the invention, the slave circuit further comprises an audio/video interface (AVI) output port, a high definition multimedia interface (HDMI) output port, or a digital video interface (DVI) output port, and the decompressed digital signal is played through the AVI output port after being processed by the DAC or played through the HDMI output port or the DVI output port.

According to an exemplary embodiment of the invention, the RFIC and the demodulator/decompressor are both digital television (TV) chips, digital audio broadcasting (DAB) chips, or global positioning system (GPS) chips or a combination of foregoing chips.

According to an exemplary embodiment of the invention, if the RFIC and the demodulator/decompressor are both digital TV chips, the interactive graphical user interface guides the user to set a digital TV.

According to an exemplary embodiment of the invention, if the RFIC and the demodulator/decompressor are both DAB chips, the interactive graphical user interface guides the user to set a digital radio.

According to an exemplary embodiment of the invention, if the RFIC and the demodulator/decompressor are both GPS chips, the interactive graphical user interface guides the user to set a GPS navigation or positioning application.

According to an exemplary embodiment of the invention, if the RFIC is a frequency-modulation (FM) broadcasting chip, the interactive graphical user interface guides the user to set a FM radio.

According to an exemplary embodiment of the invention, if the RFIC is an amplitude-modulation (AM) broadcasting chip, the interactive graphical user interface guides the user to set an AM radio.

According to an exemplary embodiment of the invention, the slave circuit includes a charger, and the handheld device controls the charger to charge the handheld device.

According to an exemplary embodiment of the invention, the handheld device is a smart phone, a personal digital assistant (PDA), a portable digital multimedia player, or a tablet personal computer.

According to an exemplary embodiment of the invention, when the user places the handheld device into the insertion device and the handheld device downloads a movie file from the Internet, the insertion device plays the movie file.

These and other exemplary embodiments, features, aspects, and advantages of the invention will be described and become more apparent from the detailed description of exemplary embodiments when read in conjunction with accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a conventional insertion speaker.

FIG. 2 is a diagram of an interactive play system according to an embodiment of the invention.

FIG. 3 is a circuit block diagram of the interactive play system in FIG. 2.

FIG. 4 is a circuit block diagram of an interactive play system according to an embodiment of the invention.

FIG. 5 is a diagram illustrating the connection between an interactive play system and an external device according to an embodiment of the invention.

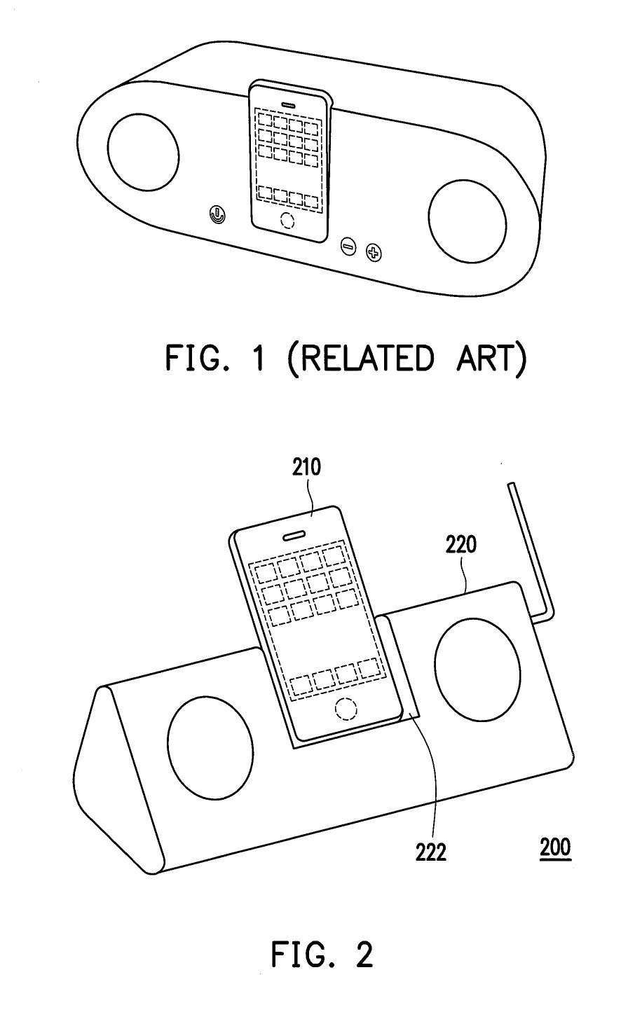

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

An interactive play system allows a handheld device to play sound and run additional functions. Thereby, a user can enjoy the convenience brought by the additional functions of the handheld device.

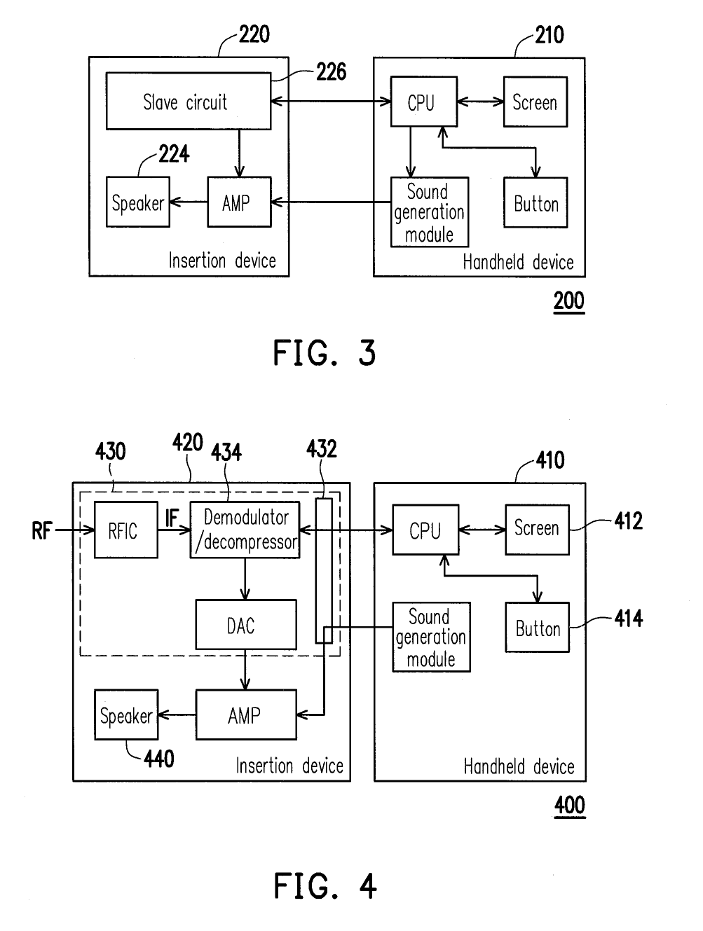

FIG. 2 is a diagram of an interactive play system according to an embodiment of the invention. FIG. 3 is a circuit block diagram of the interactive play system in FIG. 2. Referring to both FIG. 2 and FIG. 3, the interactive play system 200 includes a handheld device 210 and an insertion device 220. The handheld device 210 may be a smart phone, a personal digital assistant (PDA), a portable digital multimedia player, or a tablet personal computer. An interactive application program is embedded in the handheld device 210. The insertion device 220 includes a dock 222, an amplifier AMP, a speaker 224, and a slave circuit 226. The dock 222 carries the handheld device 210. The speaker 224 is coupled to the amplifier AMP and used for playing a sound. The slave circuit 226 is coupled to the amplifier AMP. When a user places the handheld device 210 into the dock 222 of the insertion device 220, the slave circuit 226 and the amplifier AMP are coupled to the handheld device 210, and the handheld device 210 activates the interactive application program and displays an interactive graphical user interface on the screen of the handheld device 210, so as to guide the user to set various functions of the insertion device 220. The handheld device 210 can control various functions of the slave circuit 226, and the handheld device 210 and the slave circuit 226 can have a two-way communication therebetween to transmit data, signals, or messages.

A possible pattern of an interactive play system provided by the invention has been described in foregoing embodiment. However, it should be understood by those having ordinary knowledge in the art that the insertion device 220 from different manufacturers may have different designs and accordingly the invention is not limited to being applied to the possible pattern described above. In other words, it is within the scope of the invention as long as the handheld device 210 is placed into the dock 222 of the insertion device 220 and the handheld device 210 controls the functions and settings of the insertion device 220. In order to allow those having ordinary knowledge in the art to better understand the spirit of the invention and implement the invention according to the present disclosure, a few more embodiments will be described below.

FIG. 4 is a circuit block diagram of an interactive play system according to an embodiment of the invention. The interactive play system 400 includes a handheld device 410 and an insertion device 420. The insertion device 420 has a dock (not shown in FIG. 4, please refer to the dock 222 in FIG. 2), an amplifier AMP, a speaker 440, and a slave circuit 430. The slave circuit 430 includes a connector 432, a radio frequency integrated circuit (RFIC), a demodulator/decompressor 434, and digital-to-analog converter (DAC). The connector 432 is coupled to a central processing unit (CPU) of the handheld device 410 so as to allow the handheld device 410 and the insertion device 420 to communicate with each other. The RFIC receives a radio frequency signal RF and converts the radio frequency signal RF to an intermediate frequency signal IF. The demodulator/decompressor 434 is coupled between the RFIC and the connector 432. The demodulator/decompressor 434 receives an intermediate frequency signal IF from the RFIC and demodulates and decompresses the intermediate frequency signal IF under the control of the CPU of the handheld device 410. The DAC is coupled between the demodulator/decompressor 434 and the amplifier AMP. Regarding the decompressed digital signal, the audio portion is converted by the DAC and the amplifier AMP and then played through the speaker 440, and the video portion is played on the screen 412 of the handheld device 410 or on an external screen. The technique of playing the video portion on the external screen will be explained in detail later on. In addition, when the insertion device 420 demodulates and decompresses the intermediate frequency signal IF, it can record a multimedia file in real time, wherein the multimedia file is related to the demodulated and decompressed signal.

As described above, the insertion device 420 may have no screen or button. An interactive application program is embedded in the handheld device 410. When a user places the handheld device 410 into the dock of the insertion device 420, the handheld device 410 activates the interactive application program, wherein the interactive application program is run by a CPU of the handheld device 410. Then, the handheld device 410 displays the interactive graphical user interface on its screen 412, so as to guide the user to set various functions and play mode of the slave circuit 430. The user runs various functions of the slave circuit 430 through the screen 412 and button 414 of the handheld device 410. The button 414 may be a hardware button or a software button implemented on a touch screen. The screen 412 may be a general display panel or a touch panel. However, the type of the screen 412 or the button 414 is not limited in the invention.

It should be mentioned that other functional circuits may be added into the interactive play system 400, wherein these functional circuits are also under the control of the handheld device 410. For example, the slave circuit 430 may include a charger (not shown), and the handheld device 410 may control the corresponding charging or discharging function of the charger to supply current to a rechargeable battery in the handheld device 410.

It should be noted that the RFIC and the demodulator/decompressor 434 can be designed according to the actual design, and the application range thereof is not specified herein. For example, the RFIC and the demodulator/decompressor 434 may be both digital TV chips, digital audio broadcasting (DAB) chips, or global positioning system (GPS) chips or a combination of foregoing chips. When the RFIC and the demodulator/decompressor 434 are both digital TV chips, the interactive graphical user interface can guide the user to set a digital TV. When the RFIC and the demodulator/decompressor 434 are both DAB chips, the interactive graphical user interface can guide the user to set a digital radio. When the RFIC and the demodulator/decompressor 434 are both GPS chips, the interactive graphical user interface can guide the user to set a GPS navigation or positioning application.

When the RFIC is a frequency-modulation (FM) broadcasting chip, the interactive graphical user interface can guide the user to set a FM radio. When the RFIC is an amplitude-modulation (AM) broadcasting chip, the interactive graphical user interface can guide the user to set an AM radio.

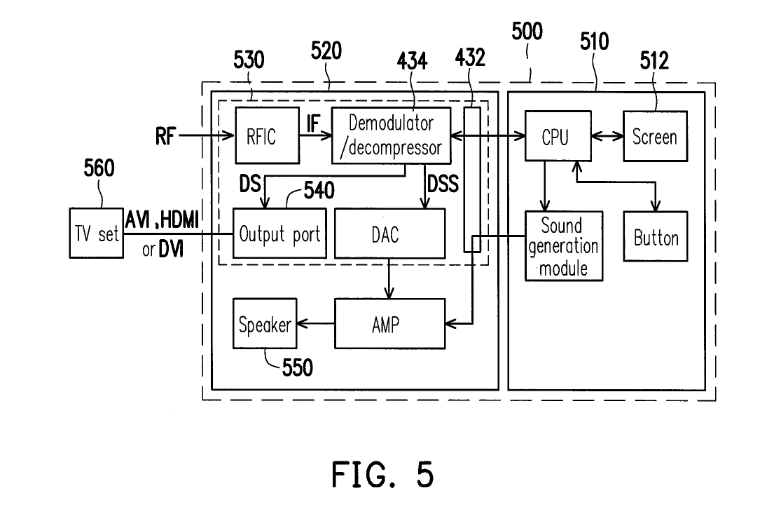

FIG. 5 is a diagram illustrating the connection between an interactive play system 500 and an external device 560 according to an embodiment of the invention. In the present embodiment, an output port 540 is further disposed in the slave circuit 530. The output port 540 may be an audio/video interface (AVI) output port, a high definition multimedia interface (HDMI) output port, or a digital visual interface (DVI) output port, and an output video or audio is sent to an external device 560 to be played through an AVI, a DVI, or a HDMI. For example, the handheld device 510 displays an interactive graphical user interface GUI. Because the insertion device 520 has the output port 540, a user can operate through the interactive graphical user interface GUI and play the video or audio through the external device 560, wherein the external device 560 is not limited to a TV set. The type of the output port 540 or the external device 560 can be determined according to the design requirement by those skilled in the art. It should be noted that the decompressed digital signal may be a digital sample sequence DSS. The digital sample sequence DSS is converted by the DAC into an analog signal and then transmitted to the amplifier AMP and the speaker to play as a sound. The decompressed digital signal may also by any other type of digital signal DS which is played through the AVI output port, the HDMI output port, or the DVI output port.

Additionally, when the user places the handheld device 510 into the insertion device 520, the user can connect to the Internet (for example, the website of YouTube) through the handheld device 510 and download a movie file from the Internet. The movie file is decompressed by the CPU of the handheld device 510. The video portion of the movie file may be played by a video device built in the handheld device 510. Or, the video portion of the movie file may also be demodulated/decompressed into the digital signal DS by the demodulator/decompressor 434 of the insertion device 520 and then output to an external TV set 560 through the output port 540 to be played. The demodulator/decompressor 434 also demodulates an intermediate frequency signal IF, decompresses the demodulated signal to generate the digital sample sequence DSS and the digital signal DS, and converts a signal received from the CPU of the handheld device 510 into the digital signal DS.

In summary, in an interactive play system provided by the invention, because the handheld device can control various functions and settings of the insertion device, the insertion device can add additional functions to the handheld device besides playing high-quality sound for the handheld device. In addition, the interactive play system in the invention can resolve the problem of sound amplification without any other function in the conventional technique and bring convenience in operation. Thereby, a user can experience the new functions and convenience brought by the handheld device and its accessories.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An interactive play system, comprising:
a handheld device, wherein an interactive application program is embedded in the handheld device; and
an insertion device, comprising:
a dock, for carrying the handheld device;
an amplifier;
a speaker, coupled to the amplifier, for playing a sound; and
a slave circuit, coupled to the amplifier;
wherein when the handheld device is placed into the dock of the insertion device to activate the interactive application program, the handheld device displays an interactive graphical user interface, the slave circuit and the amplifier are coupled to the handheld device so as to guide a user to set the insertion device, and the handheld device controls various functions of the slave circuit.

2. The interactive play system according to claim 1, wherein the slave circuit comprises:
a connector, coupled to the handheld device to allow the handheld device and the insertion device to communicate with each other;
a radio frequency integrated circuit (RFIC), for receiving a radio frequency signal and converting the radio frequency signal to an intermediate frequency (IF) signal;
a demodulator/decompressor, coupled between the RFIC and the connector, for receiving the IF signal from the RFIC and demodulating and decompressing the IF signal under the control of a central processing unit (CPU) of the handheld device; and
a digital-to-analog converter (DAC), coupled between the demodulator/decompressor and the amplifier, wherein a decompressed digital signal is processed by the DAC and the amplifier and played through the speaker.

3. The interactive play system according to claim 2, wherein the insertion device records a multimedia file in real time when the insertion device demodulates and decompresses the IF signal.

4. The interactive play system according to claim 2, wherein the slave circuit further comprises an audio/video interface (AVI) output port, a high definition multimedia interface (HDMI) output port, or a digital video interface (DVI) output port, and the decompressed digital signal is played through the AVI output port after being processed by the DAC or played through the HDMI output port or the DVI output port.

5. The interactive play system according to claim 2, wherein the RFIC and the demodulator/decompressor are both digital TV chips, digital audio broadcasting (DAB) chips, or global positioning system (GPS) chips, or a combination of foregoing chips.

6. The interactive play system according to claim 5, wherein when the RFIC and the demodulator/decompressor are both digital TV chips, the interactive graphical user interface guides the user to set a digital TV.

7. The interactive play system according to claim 5, wherein when the RFIC and the demodulator/decompressor are both DAB chips, the interactive graphical user interface guides the user to set a digital radio.

8. The interactive play system according to claim 5, wherein when the RFIC and the demodulator/decompressor are both GPS chips, the interactive graphical user interface guides the user to set a GPS navigation or positioning application.

9. The interactive play system according to claim 2, wherein when the RFIC is a frequency-modulation (FM) broadcasting chip, the interactive graphical user interface guides the user to set a FM radio.

10. The interactive play system according to claim 2, wherein when the RFIC is an amplitude-modulation (AM) broadcasting chip, the interactive graphical user interface guides the user to set an AM radio.

11. The interactive play system according to claim 1, wherein the slave circuit comprises a charger, and the handheld device controls the charger to charge the handheld device.

12. The interactive play system according to claim 1, wherein the handheld device is a smart phone, a personal digital assistant (PDA), a portable digital multimedia player, or a tablet personal computer.

13. The interactive play system according to claim 1, wherein when the user places the handheld device into the insertion device and the handheld device downloads a movie file from the Internet, the insertion device plays the movie file.
